(19) United States
(12) Patent Application Publication
(10) Pub. No.: US 2011/0215242 A1
(43) Pub. Date: Sep. 8, 2011

(54) Particle beam device and method for operation of a particle beam device

(76) Inventor: Dirk Preikszas, Oberkochen (DE)

(21) Appl. No.: 12/931,356

(22) Filed: Jan. 27, 2011

(30) Foreign Application Priority Data
Jan. 28, 2010 (DE) 10 2010 001 346.3

(51) Int. Cl. H01J 37/28

(52) U.S. Cl. 250/307; 250/310

(57) ABSTRACT

A particle beam device and a method for operation of a particle beam device are disclosed. The particle beam device has a sample chamber, a sample arranged in the sample chamber, a first particle beam column, a second particle beam column and at least one detector arranged in a first cavity in a first hollow body. The first cavity has a first inlet opening. The first particle beam column and the second particle beam column are arranged on one plane, while the detector is not arranged on that plane. At least one control electrode is arranged on the first particle beam column. The second particle beam column has a terminating electrode. A first hollow body voltage, a control electrode voltage and/or a terminating electrode voltage are/is chosen such that first interaction particles and/or second interaction particles enter the first cavity in the first hollow body through the first inlet opening.

### TECHNICAL FIELD

This application relates to a particle beam device and to a method for operation of a particle beam device.

### BACKGROUND OF THE INVENTION

Electron beam devices, in particular a scanning electron microscope (also referred to in the following text as SEM) are used to examine samples, in order to obtain knowledge about the characteristics and behavior of these samples in specific conditions.

In the case of an SEM, an electron beam (also referred to in the following text as the primary electron beam) is generated by a beam generator, and is focused by a beam guidance system, in particular an objective lens, onto a sample to be examined. The primary electron beam is passed over a surface of the sample to be examined, in the form of a raster, by a deflection device. The electrons in the primary electron beam in this case interact with the material of the sample to be examined. The interaction results in particular in interaction particles. In particular, electrons are emitted from the surface of the sample to be examined (so-called secondary electrons), and electrons are scattered back from the primary electron beam (so-called back-scattered electrons). The secondary electrons and back-scattered electrons are detected, and are used for image production. This therefore results in an image of the surface of the sample to be examined.

It is also known from the prior art for combination device to be used to examine samples, in which both electrons and ions can be passed to a sample to be examined. By way of example, it is known for an SEM to additionally be equipped with an ion beam column. An ion beam generator which is arranged in the ion beam column is used to generate ions, which are used for preparation of a sample, (for example removal of a layer of the sample or application of material to the sample), or else for imaging. In this case, the SEM is used in particular to observe the preparation, or else for further examination of the prepared or unprepared sample.

By way of example, reference is made to DE 10 2006 059 162 A1, which is incorporated herein by reference, with respect to the prior art cited above.

In addition to the already mentioned image production, it is also possible to analyze the energy and/or the mass of interaction particles in more detail. For example, a method is known from mass spectroscopy in which secondary ions are examined in more detail. The method is known by the abbreviation SIMS (secondary ion mass spectroscopy). In this method, the surface of a sample to be examined is irradiated with a focused primary ion beam. The interaction particles generated in the process, and which are in the form of secondary ions emitted from the surface of the sample, are detected and examined by mass spectrometry. In the process, the secondary ions are selected and identified on the basis of their ion mass and their ion charge, thus allowing conclusions to be drawn about the composition of the sample.

When analyzing interaction particles, it is desirable to detect as many of the interaction particles as possible in order, for example, to allow good image production or to allow a good statement to be made about the characteristics of the interaction particles, and therefore also of the characteristics of the sample being examined. This results in an interest in good efficiency of a detector (also referred to in the following text as the detector efficiency), with which the interaction particles are detected. Furthermore, in the analysis of the interaction particles, there is also an interest in the energy resolution of the energies of the interaction particles.

It is possible to provide an analysis apparatus, which has a detector for detection of the interaction particles, with an input aperture in order, for example, to shield electrical fields from a primary electron beam or primary ion beam. In order to achieve good detector efficiency in this case as well, it is possible to arrange the input aperture as close as possible to the sample to be examined. In addition, the input aperture can be provided with an extraction potential for generating an extraction field such that as many interaction particles as possible pass through the input aperture into the analysis apparatus.

It is known for a so-called Everhart-Thornley detector to be used for detection of interaction particles in the form of secondary electrons or back-scattered electrons. This detector has a scintillator and a photomultipler. The scintillator is surrounded by a collector, which has an inlet opening in which a grid is arranged. The inlet opening is completely filled by the grid. The collector and the grid are at a variable potential, for example from (−400) V to 400 V. When the grid is at a positive potential, secondary electrons are attracted and detected. However, when the grid is at a negative potential of below (−50) V, then secondary electrons can no longer pass through the grid. In fact, high-energy back-scattered electrons are passed through the grid, and then strike the scintillator.

The extraction field provided by the potential on the grid is generally deformed by the sample and components of an objective lens of a particle beam device. This can lead to the extraction field being inadvertently changed, thus influencing the detector efficiency. There is therefore a need to detect interaction particles both with high energy resolution and with good detector efficiency.

Accordingly, it would be desirable to specify a particle beam device in which interaction particles can be detected with high energy resolution and/or with high efficiency.

### SUMMARY OF THE INVENTION

According to a system described herein, a particle beam device may have a sample chamber in which a sample to be examined is arranged. The particle beam device furthermore may have a first particle beam column, having a first optical axis. The first particle beam column may have a first beam generator for generating a first particle beam and may have a first objective lens for focusing the first particle beam onto the sample. When the first particle beam strikes the sample, interactions between the first particle beam and the sample may create first interaction particles. By way of example, the first particle beam column may be in the form of an ion beam column, in which the first beam generator generates an ion beam as the first particle beam. The interaction of the ion beam with the sample may result in particular in secondary ions, which are emitted from the sample.

Furthermore, the particle beam device according to the system described herein may have a second particle beam column with a second optical axis. The second particle beam column may have a second beam generator for generating a second particle beam and may have a second objective lens for focusing the second particle beam onto the sample, wherein, when the second particle beam strikes the sample, interactions between the second particle beam and the sample may create second interaction particles. By way of example, the second particle beam column may be in the form of an electron beam column.

In particular, one exemplary embodiment provides for the second particle beam column to be the beam column of a scanning electron microscope. This may be used to generate a primary electron beam by the second beam generator, which the second objective lens focuses onto the sample. The primary electron beam may be passed in the form of a raster scan over a surface of the sample to be examined, by a deflection device. In the process, the electrons in the primary electron beam may interact with the material of the sample. The interaction may result, in particular, in second interaction particles. In particular, secondary electrons may be emitted from the surface of the sample, and electrons in the primary electron beam may be scattered back (back-scattered electrons). The secondary electrons and the back-scattered electrons may be detected, and may be used for image production. An image of the surface of the sample to be examined may therefore be obtained.

The particle beam device according to the system described herein furthermore has at least one detector, which may be arranged in a first cavity in a first hollow body, wherein the first cavity may have a first inlet opening.

Furthermore, the particle beam device according to the system described herein provides for the first optical axis of the first particle beam column and the second optical axis of the second particle beam column to be arranged on one plane. In contrast, a third axis which is aligned inclined with respect to or at right angles to the abovementioned plane may run from the first inlet opening (for example essentially from the center of the first inlet opening) to the detector (for example essentially to the center of the detector). In each case, the third axis does not lie on the plane on which the first optical axis and the second optical axis lie. If the arrangement of the first particle beam column, of the second particle beam column and of the detector with respect to one another are accordingly considered, then this arrangement may correspond to an arrangement in at least two, and in particular three, different dimensions.

Furthermore, the sample may be at a sample potential in the particle beam device according to the system described herein. Furthermore, the first hollow body may be at a first hollow body potential, wherein a first hollow body voltage is a first potential difference between the first hollow body potential and the sample potential. In addition, at least one control electrode which is at a control electrode potential may be arranged on the first particle beam column. Furthermore, a control electrode voltage may be provided, which is a third potential difference between the control electrode potential and the sample potential. A terminating electrode which is at a terminating electrode potential may be in turn arranged on the second particle beam column. Furthermore, a terminating electrode voltage may be provided, wherein the terminating electrode voltage may be a fourth potential difference between the terminating electrode potential and the sample potential.

The first hollow body voltage, the control electrode voltage and/or the terminating electrode voltage may be chosen such that an extraction field is generated, such that the first interaction particles and/or the second interaction particles may enter the first cavity in the first hollow body through the first inlet opening. This results in the first interaction particles and/or the second interaction particles striking the detector.

Analysis has shown that the particle beam device according to the system described herein on the one hand ensures good energy resolution and on the other hand good detector efficiency for the detection of the first interaction particles and/or the second interaction particles, for example secondary ions. The latter, in particular, is achieved in that the sample potential, the first hollow body potential, the control electrode potential and/or the terminating electrode potential may be matched to one another so as to generate an extraction field, such that a sufficient number of first interaction particles and/or second interaction particles may pass through the inlet opening of the cavity, and may be detected by the detector. If a beam guide tube for the first particle beam column and/or a beam guide tube for the second particle beam column are likewise at a potential, then, in one embodiment of the system described herein, this potential may also be taken into account in the matching of the sample potential, of the first hollow body potential, of the control electrode potential and/or of the terminating electrode potential.

The abovementioned matching of the sample potential, of the first hollow body potential, of the control electrode potential and/or of the terminating electrode potential in order to achieve a sufficient number of first interaction particles and/or second interaction particles may be achieved, for example, by varying at least one of the abovementioned potentials until a previously experimentally measured detector efficiency or a computational simulated detector efficiency has been achieved. Alternatively or in addition to this, a further embodiment provides for values which for at least one of the abovementioned potentials, which values have already been stored in a data memory, to be read and to be used, in which case the values may be stored in the data memory as a function of the position of the sample with respect to the detector, in particular as a function of a tilted position of the sample. Alternatively or additionally, the values may be stored in the data memory as a function of the working distance, that is to say a position of a sample holder along a z-axis. In particular, a set of values for the first hollow body potential, the control electrode potential and/or the terminating electrode potential may be stored in the data memory for a multiplicity of positions of the sample, in particular for a multiplicity of tilted positions, and/or for a multiplicity of working distances. Alternatively or in addition to this, values for at least one of the abovementioned potentials may be interpolated by the values stored in the data memory.

In one embodiment of the particle beam device according to the system described herein, the particle beam device may additionally or alternatively be provided with at least one of the following features: the first hollow body voltage may be set by a first voltage supply unit, the control electrode voltage may be set by a third voltage supply unit, or the terminating electrode voltage may be set by a fourth voltage supply unit.

In one embodiment of the particle beam device according to the system described herein, the detector may additionally or alternatively be at a detector potential, wherein a detector voltage may be a second potential difference between the detector potential and the sample potential. By way of example, the detector voltage may be set by a second voltage supply unit. The first hollow body voltage, the detector voltage, the control electrode voltage and/or the terminating electrode voltage may be chosen in such a way that an extraction field is generated such that the first interaction particles and/or the second interaction particles enter the first cavity in the first hollow body through the first inlet opening. The sample potential, the first hollow body potential, the detector potential, the control electrode potential and/or the terminating electrode potential may therefore be matched to one another in such a way that an extraction field is generated, as a result of which a sufficient number of first interaction particles and/or second interaction particles may pass through the first inlet opening in the first cavity, and may be detected by the detector.

In yet another embodiment of the particle beam device according to the system described herein, the control electrode may additionally or alternatively be arranged on an outer surface of the first particle beam column. Alternatively, or in addition to this, the control electrode may be arranged in a recess on an outer surface of the first particle beam column. Furthermore, additionally or as an alternative to this, the control electrode may be arranged in the recess such that an outer surface of the control electrode and the outer surface of the first particle beam column may form a continuous surface. However, the system described herein is not restricted to a specific type, shape and arrangement of the control electrode. In fact, any suitable control electrode may be used. In particular, in one embodiment of the particle beam device according to the system described herein, the control electrode may partially surround the first particle beam column. As an alternative to this, the control electrode may completely surround the first particle beam column.

In one embodiment of the particle beam device according to the system described herein, the sample potential may alternatively or additionally be ground (0 V). Furthermore, the first hollow body potential may additionally or as an alternative to this be in the range from (−100) V to (−500) V. Additionally or alternatively to this, the detector potential may be in the range from (−10) V to (−500) V. In a further embodiment of the system described herein, the control electrode potential may additionally or alternatively be in the range from 100 V to 800 V, and/or the terminating electrode potential may be in the range from (−50) V to (−200) V. In a further embodiment of the particle beam device according to the system described herein, a beam guide tube for the second particle beam column may be at a potential in the range from 1 kV to 30 kV, for example 8 kV, with respect to the sample potential.

In a further embodiment of the particle beam device according to the system described herein, not only may the detector additionally or as an alternative to this be arranged in a cavity in a single hollow body, but the detector may be arranged in a plurality of hollow bodies. This embodiment of the particle beam device therefore may have a second hollow body with a second cavity. The second hollow body may be at a second hollow body potential. A second hollow body voltage may be a fifth potential difference between the second hollow body potential and the sample potential. The second hollow body voltage may be set by a fifth voltage supply unit. The first hollow body and the second hollow, body may, for example, be in the form of tubular electrodes. In particular, the second hollow body may be held in the first cavity in the first hollow body. The detector may then be held in the second cavity in the second hollow body. The first hollow body potential and the second hollow body potential may be of the same magnitude. In alternative embodiments, the first hollow body potential and the second hollow body potential may be of different magnitudes. Analyses have shown that an extraction field may be generated by a suitable choice of the first hollow body potential and of the second hollow body potential, taking account of the already previously mentioned sample potentials, the terminating electrode potential, the detector potential and/or the control electrode potential, such that a high detector efficiency is achieved. A sufficient number of first interaction particles and/or second interaction particles may pass through the first inlet opening in the first cavity and through the second inlet opening in the second cavity, and may be detected by the detector.

In a further embodiment of the particle beam device, the second hollow body potential may be additionally or alternatively ground (0 V), and the first hollow body potential may be designed to be different to the second hollow body potential. As an alternative to this, the first hollow body potential and the second hollow body potential may not be ground (0 V).

In a further embodiment of the particle beam device according to the system described herein, the first hollow body voltage, the second hollow body voltage and the detector voltage may additionally or alternatively be set by a single voltage supply unit, for example by the first voltage supply unit. In a further embodiment, the first hollow body voltage and the detector voltage may alternatively be set by a single voltage supply unit, for example by the first voltage supply unit. In yet another embodiment, the second hollow body voltage and the detector voltage may alternatively be set by a single voltage supply unit, for example by the fifth voltage supply unit.

In yet another embodiment of the particle beam device according to the system described herein, the particle beam device may have one of the following features:
the first particle beam column may be in the form of an ion beam column, and the second particle beam column may be in the form of an electron beam column, or
the first particle beam column may be in the form of an ion beam column, and the second particle beam column may be in the form of an ion beam column.

The system described herein also relates to a method for operation of a particle beam device which has at least one of the abovementioned features or a combination of the abovementioned features. In particular, in the method according to the system described herein, the first hollow body voltage, the detector voltage, the control electrode voltage and the terminating electrode voltage may be provided. Furthermore, the first hollow body voltage, the detector voltage, the control electrode voltage and/or the terminating electrode voltage may be set such that the first interaction particles and/or the second interaction particles may enter the first cavity in the first hollow body through the first inlet opening, as a result of which the first interaction particles and/or the second interaction particles may be detected by the detector. In principle, the sample potential, the first hollow body potential, the detector potential, the control electrode potential and/or the terminating electrode potential may be matched to one another such that an extraction field is generated, such that a sufficient number of first interaction particles and/or second interaction particles may pass through the first inlet opening in the first cavity and may be detected by the detector.

If the particle beam device is equipped with two hollow bodies, one embodiment of the method according to the system described herein additionally or alternatively provides for a first hollow body voltage and a second hollow body voltage to be provided. Furthermore, the first hollow body voltage and the second hollow body voltage may be set such that the first interaction particles and/or the second interaction particles may enter the second cavity in the second hollow body through the first inlet opening in the first cavity and the second inlet opening in the second cavity. They may then be detected by the detector. The sample potential, the first hollow body potential, the second hollow body potential, the detector potential, the control electrode potential and/or the terminating electrode potential may be matched to one another such that an extraction field is generated, as a result of which a sufficient number of first interaction particles and/or second interaction particles may pass through the second inlet opening in the second cavity, and may be detected by the detector.

In one embodiment of the method according to the system described herein, the sample potential may be ground (0 V). Furthermore, additionally or as an alternative to this, the first hollow body potential and/or the second hollow body potential may be set to a value in the range from (−100) V to (−500) V. Additionally or as an alternative to this, the detector potential may be set to a value in the range from (−10) V to (−500) V. In a further embodiment of the method according to the system described herein, the control electrode potential may additionally or alternatively be set to a value in the range from 100 V to 800 V, and/or the terminating electrode potential may be set to a value in the range from (−50) V to (−200) V. In a further embodiment of the method according to the system described herein, the beam guide tube for the second particle beam column may be set to a potential in the range from 1 kV to 30 kV, for example 8 kV, with respect to the sample potential.

By way of example, the sample potential, the first hollow body potential, the second hollow body potential, the detector potential, the control electrode potential and/or the terminating electrode potential may be set in order to achieve a sufficient number of first interaction particles and/or second interaction particles, by varying at least one of the abovementioned potentials until a previously experimentally measured detector efficiency or a computationally simulated detector efficiency is achieved. Alternatively or in addition to this, a further embodiment provides for values which are already stored in a data memory to be read and to be used for at least one of the abovementioned potentials, wherein the values in the data memory may be stored as a function of the position of the sample with respect to the detector, in particular as a function of a tilted position of the sample. Alternatively or additionally, the values may be stored in the data memory as a function of the working distance, that is to say of a position of a sample holder along a z-axis. In particular, a set of values for the first hollow body potential, the second hollow body potential, the control electrode potential and/or the terminating electrode potential may be stored in the data memory for each of a multiplicity of positions of the sample, in particular for a multiplicity of tilted positions, and/or for a multiplicity of working distances. Alternatively or in addition to this, values for at least one of the abovementioned potentials may be interpolated by the values stored in the data memory.

### BRIEF DESCRIPTION OF THE DRAWINGS

Embodiments of the system described herein will now be explained in more detail with reference to the figures, in which:

FIG. 1 shows a schematic illustration of a particle beam device having a first particle beam column and having a second particle beam column according to an embodiment of the system described herein;

FIG. 2 shows a schematic and perspective illustration of the particle beam device as shown in FIG. 1;

FIG. 3 shows a schematic illustration of an area of a sample which is arranged in the particle beam device as shown in FIG. 2;

FIG. 4 shows a schematic illustration of potential lines in the area of the sample, as shown in FIG. 3;

FIG. 5 shows a schematic illustration of an area of a sample which is the basis for a simulation according to an embodiment of the system described herein;

FIG. 5A shows a schematic illustration of potential lines in the area of the sample as shown in FIG. 5;

FIG. 6 shows a further schematic illustration of an area of a sample which is arranged in the particle beam device as shown in FIG. 2;

FIG. 7 shows yet another schematic illustration of an area of a sample which is arranged in the particle beam device as shown in FIG. 2, and

FIG. 8 shows yet another schematic illustration of an area of a sample which is arranged in the particle beam device as shown in FIG. 2.

### DETAILED DESCRIPTION OF VARIOUS EMBODIMENTS

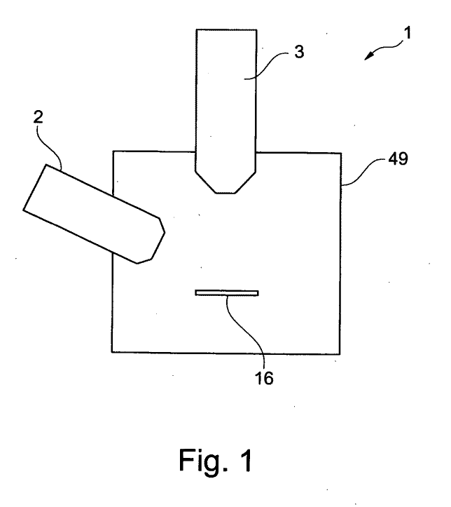

FIG. 1 shows a schematic illustration of one embodiment of a particle beam device 1 according to the system described herein. The particle beam device 1 has a first particle beam column 2 in the form of an ion beam column, and a second particle beam column 3 in the form of an electron beam column. As an alternative to this, both the first particle beam column 2 and the second particle beam column 3 may each be in the form of an ion beam column. The first particle beam column 2 and the second particle beam column 3 are arranged on a sample chamber 49 in which a sample 16 to be examined is arranged.

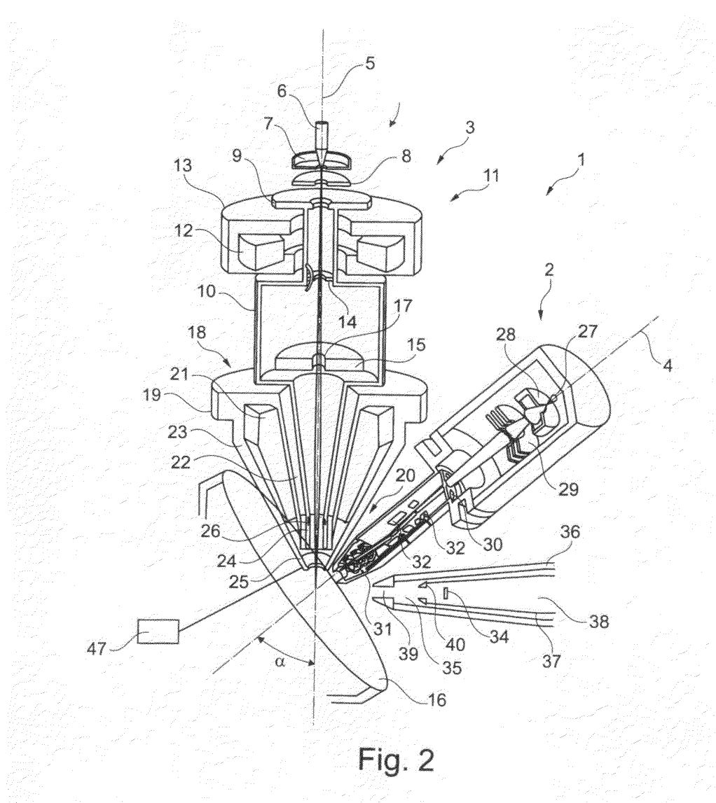

FIG. 2 shows a more detailed illustration of the particle beam device 1 as shown in FIG. 1. The sample chamber 49 is not illustrated, for clarity reasons. The first particle beam column 2, in the form of the ion beam column, has a first optical axis 4. Furthermore, the second particle beam column 3, in the form of the electron beam column, has a second optical axis 5.

The following text first of all describes the second particle beam column 3 in the form of the electron beam column. The second particle beam column 3 has a second beam generator 6, a first electrode 7, a second electrode 8 and a third electrode 9. By way of example, the second beam generator 6 is a thermal field emitter. The first electrode 7 acts as a suppressor electrode, while the second electrode 8 acts as an extractor electrode. The third electrode 9 is in the form of an anode and at the same time forms one end of a beam guide tube 10. The second beam generator 6 generates a second particle beam in the form of an electron beam. Electrons which emerge from the second beam generator 6 are accelerated to the anode potential because of a potential difference between the second beam generator 6 and the third electrode 9, for example in the range from 1 kV to 30 kV. The second particle beam, in the form of the electron beam, passes through the beam guide tube 10 and is focused onto the sample 16 to be examined. This will be described in more detail further below.

The beam guide tube 10 passes through a collimator arrangement 11 which has a first annular coil 12 and a yoke 13. Seen in the direction from the second beam generator 6 to the sample 16, the collimator arrangement 11 is followed by a variable pinhole diaphragm 14 and a first detector 15 with a central opening 17 in the beam guide tube 10 along the second optical axis 5. The beam guide tube 10 then passes through a hole in a second objective lens 18. The second objective lens 18 is used for focusing the second particle beam onto the sample 16. For this purpose, the second objective lens 18 has a magnetic lens 19 and an electrostatic lens 20. The magnetic lens 19 is provided with a second annular coil 21, an inner pole shoe 22 and an outer pole shoe 23. The electrostatic lens 20 has one end 24 of the beam guide tube 10 and a terminating electrode 25. The end 24 of the beam guide tube 10 and the terminating electrode 25 form an electrostatic delay device. The end 24 of the beam guide tube 10, together with the beam guide tube 10, are at anode potential, while the terminating electrode 25 and the sample 16 are at a lower potential than the anode potential. This allows the electrons in the second particle beam to be braked to a desired energy level, which is required for the examination of the sample 16. The second particle beam column 3 furthermore has raster device 26 by which the second particle beam is deflected, and can be scanned in a raster pattern over the sample 16.

For imaging, the first detector 15, which is arranged in the beam guide tube 10, detects secondary electrons and/or back-scattered electrons which are created because of the interaction of the second particle beam with the sample 16. The signals produced by the first detector 15 are transmitted to an electronic unit (not illustrated), for imaging.

The sample 16 is arranged on a sample stage (not illustrated), by which the sample 16 is arranged such that it can move on three axes which are arranged perpendicular to one another (specifically an x axis, a y axis and a z axis). Furthermore, the sample stage can be rotated about two rotation axes which are arranged at right angles to one another. It is therefore possible to move the sample 16 to a desired position.

As already mentioned above, the reference symbol 2 denotes the first particle beam column in the form of the ion beam column. The first particle beam column 2 has a first beam generator 27 in the form of an ion source. The first beam generator 27 is used to generate a first particle beam in the form of an ion beam. Furthermore, the first particle beam column 2 is provided with an extraction electrode 28 and a collimator 29. The collimator 29 is followed by a variable aperture 30 along the first optical axis 4 in the direction of the sample 16. The first particle beam is focused onto the sample 16 by a first objective lens 31 in the form of focusing lenses. Raster electrodes 32 are provided, in order to scan the first particle beam over the sample 16 in a raster pattern.

When the first particle beam strikes the sample 16, the first particle beam interacts with the material of the sample 16. In the process, first interaction particles are generated, in particular secondary ions, which are emitted from the sample 16. These are now detected by a second detector 34, which will be described in more detail in the following text.

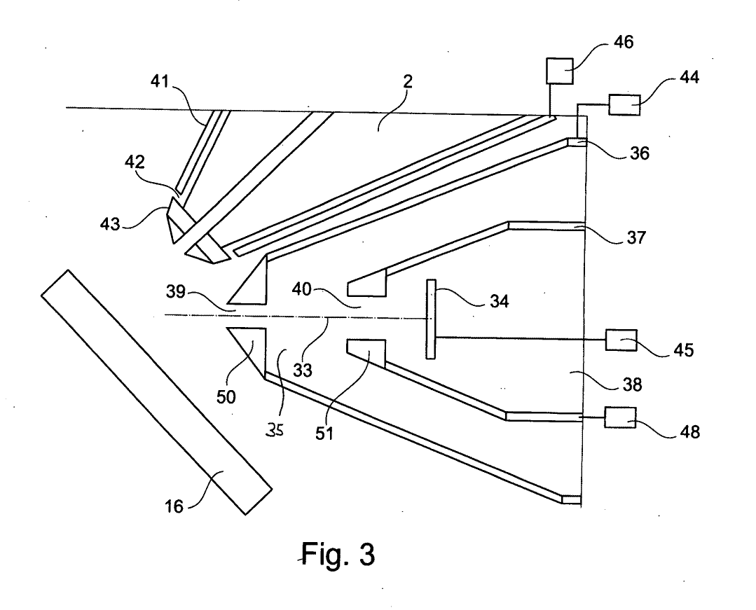

A second hollow body 37 is arranged in a first cavity in a first hollow body 36 in the form of a tubular electrode, and has a second cavity 38. The second hollow body is also in the form of a tubular electrode. The second detector 34 is arranged in the second cavity 38. The first cavity 35 has a first inlet opening 39. Furthermore, the second cavity 38 has a second inlet opening 40. A third axis 33 runs essentially to the center of the second detector 34, essentially from the center of the first inlet opening 39 and essentially from the center of the second inlet opening 40 (cf. FIG. 3).

The first optical axis 4 of the first particle beam column 2 and the second optical axis 5 of the second particle beam column 3 are arranged on one plane. In contrast, the third axis 33 is aligned inclined with respect to or at right angles to the abovementioned plane. The third axis 33 does not lie on the plane on which the first optical axis 4 and the second optical axis 5 are arranged. The arrangement of the first particle beam column 2, of the second particle beam column 3 and of the second detector 34 with respect to one another corresponds to an arrangement in three different dimensions.

FIG. 3 shows a more detailed schematic illustration of an area as shown in FIG. 2, specifically the area of the sample 16. The figure shows that end of the first particle beam column 2 which is arranged in the area of the sample 16, the second detector 34 as well as the first hollow body 36 and the second hollow body 37. FIG. 3 does not show the second particle beam column 3. That end of the first particle beam column 2 which is arranged in the area of the sample 16 has a control electrode 41. The intention is for the control electrode 41 to partially or completely surround the first particle beam column 2. Furthermore, the control electrode 41 is arranged in a recess 42 on an outer surface 43 of the first particle beam column 2. The outer surface of the control electrode 41 and the outer surface 43 of the first particle beam column 2 form a continuous surface. However, it is explicitly mentioned that the system described herein is not restricted to the abovementioned arrangement of the control electrode 41. In fact, the control electrode 41 may assume any shape and can be arranged in a way that is suitable for the system described herein. For example, the control electrode 41 may also be designed to be like a film, with the control electrode 41 which is like a film being wound around the first particle beam column 2. In addition, alternative embodiments provide for no recess to be formed on the outer surface 43 of the first particle beam column 2.

The first hollow body 36 is at a first hollow body potential. A first hollow body voltage is a first potential difference between the first hollow body potential and the sample potential. In this exemplary embodiment, ground potential (0 V) is used as the sample potential, although the sample potential is not restricted to ground potential. In fact, it may also assume a different value. The first hollow body voltage and therefore the first hollow body potential can be set by a first voltage supply unit 44.

Furthermore, the second detector 34 is at a detector potential. A detector voltage is a second potential difference between the detector potential and the sample potential. The detector voltage and therefore the detector potential can be set by a second voltage supply unit 45.

The control electrode 41 is also at a potential, specifically the control electrode potential. A control electrode voltage is a third potential difference between the control electrode potential and the sample potential. The control electrode voltage and therefore the control electrode potential can be set by a third voltage supply unit 46.

A somewhat similar situation applies to the terminating electrode 25 of the second particle beam column 3. The terminating electrode 25 is at a potential, specifically the terminating electrode potential. A terminating electrode voltage is a fourth potential difference between the terminating electrode potential and the sample potential. The terminating electrode voltage and therefore the terminating electrode potential can be set by a fourth voltage supply unit 47 (cf. FIG. 2).

It is envisaged that the second hollow body 37 will also be at a potential, specifically at a second hollow body potential. A second hollow body voltage is a fifth potential difference between the second hollow body potential and the sample potential. The second hollow body voltage and therefore the second hollow body potential can be set by a fifth voltage supply unit 48. The first hollow body potential and the second hollow body potential may be of the same magnitude. In further embodiments, the first hollow body potential and the second hollow body potential have different magnitudes.

The sample potential, the first hollow body potential, the second hollow body potential, the detector potential, the control electrode potential and/or the terminating electrode potential are now matched to one another such that an extraction field is generated which ensures that an adequate number of first interaction particles in the form of secondary ions pass through the first inlet opening 39 in the first cavity 35 in the first hollow body 36 and through the second inlet opening 40 in the second cavity 38 in the second hollow body 37, and are detected by the second detector 34.

As already mentioned above, the sample potential in this embodiment is ground potential. It is also envisaged that the first hollow body potential and/or the second hollow body potential will be in the range from (−100) V to (−500) V, the detector potential will be in the range from (−10) V to (−500) V, the control electrode potential will be in the range from 100 V to 800 V and/or the terminating electrode potential will be in the range from (−50) V to (−200) V.

It has been found that when the potential on the beam guide tube 10 in the second particle beam column 3 is 8 kV, essentially 8% of the secondary ions reach the second detector 34 when the first hollow body potential is set to (−200) V, the second hollow body potential is set to (−20) V, the detector potential is set to (−20) V, the terminating electrode potential is set to (−81) V and the control electrode potential is set to 355 V. A first hollow body potential of (−400) V, a second hollow body potential of (−50) V, a detector potential of (−50) V, a terminating electrode potential of (−90) V and a control electrode potential of 600 V result in essentially 15% of the secondary ions reaching the second detector 34.

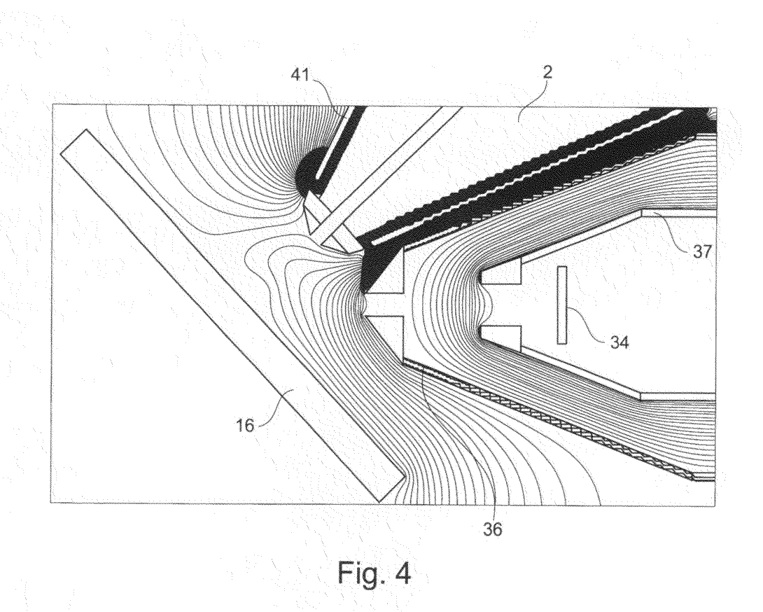

FIG. 4 shows a schematic illustration of the area illustrated in FIG. 3, with the first hollow body potential being set to (−200) V, the second hollow body potential being set to (−20) V, the detector potential being set to (−20) V, the terminating electrode potential being set to (−81) V and the control electrode potential being set to 355 V. FIG. 4 shows a profile of potential lines of an extraction field, which ensures that the first interaction particles in the form of the secondary ions reach the second detector 34. The interval between the individual potential lines is essentially 10 V.

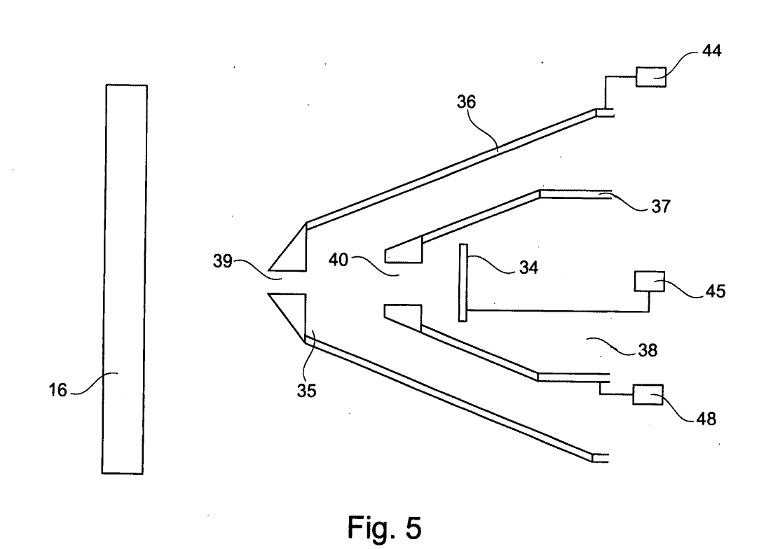

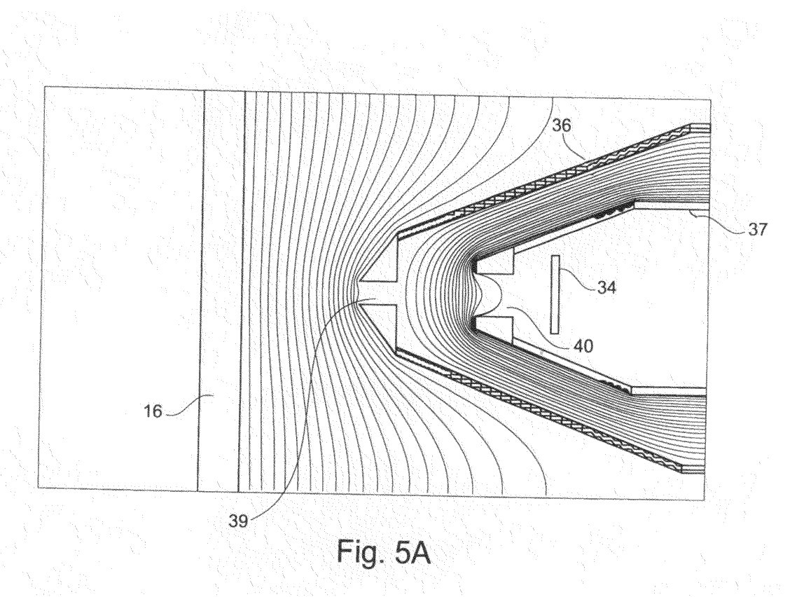

A simulation of a comparison arrangement was carried out in order to check the detector efficiency of the system described herein. The comparison arrangement is illustrated in FIG. 5. FIG. 5 shows the area of the sample 16 of a particle beam device 1, in which case this simulation assumes that the particle beam device 1 has no particle beam column. The simulation assumes that there are no disturbing influences whatsoever, in particular influences which can originate from a particle beam column. The same components in FIGS. 1 to 3 are annotated with the same reference symbols in FIG. 5. In this exemplary embodiment the first hollow body 36, the second hollow body 37 and the second detector 34, which is arranged in the second cavity 38 in the second hollow body 37, are arranged essentially at right angles in front of and to the sample 16. This is advantageous for good detector efficiency, because the arrangement in the immediate vicinity of the sample 16 makes it possible for the second detector 34 to detect a very large number of the secondary ions. An arrangement such as this, as is shown in FIG. 5, is, however, generally not feasible, since the physical space to do this often does not exist in a particle beam device, and/or further conditions (for example the movement of the sample 16) do not permit an arrangement such as this. In the arrangement illustrated in FIG. 5, the intention is for individual components to be at a potential. The sample 16 is at the sample potential which, in this exemplary embodiment, corresponds to ground potential. Furthermore, the second detector 34 is at the detector potential, which can be set by the second voltage supply unit 45. The first hollow body 36 is at the first hollow body potential, which can be set by the first voltage supply unit 44. In addition, the second hollow body 37 is at a potential, specifically the second hollow body potential, which can be set by the fifth voltage supply unit 48. Reference is also made to the statements made above, with respect to the setting capability.

In the exemplary embodiment illustrated in FIG. 5, the detector potential of the second detector 34 and the second hollow body potential are chosen to be the same. In other exemplary embodiments, the detector potential and the second hollow body potential have different values.

As already mentioned above, the sample potential in this embodiment is ground potential (0 V). It is also envisaged that the first and the second hollow body potentials will be in the range from (−200) V to (−500) V, and that the detector potential will be in the range from (−10) V to (−500) V. It has been found that a first hollow body potential of (−200) V, a second hollow body potential of (−20) V and a detector potential of (−20) V result in an extraction field such that essentially 9% of the secondary ions reach the second detector 34. A first hollow body potential of (−400) V, a second hollow body potential of (−50) V and a detector potential of (−50) V result in an extraction field in which essentially 17% of the secondary ions reach the second detector 34. FIG. 5A illustrates a profile of the potential lines of the extraction field. To this extent, the simulation has shown that the system described herein has essentially the same detector efficiency as the comparison arrangement shown in FIG. 5

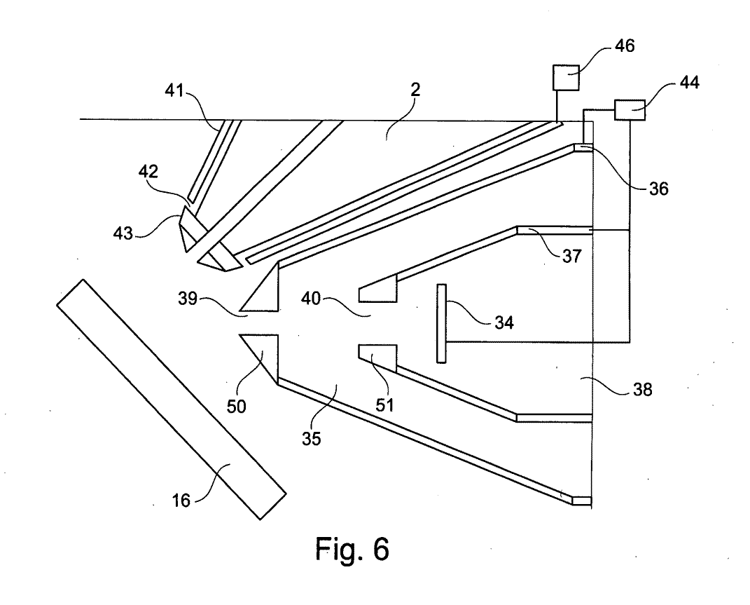

FIG. 6 shows a further schematic illustration of the area of the sample 16. FIG. 6 is based on FIG. 3, as a result of which reference will be made first of all to the statements made above. In contrast to the exemplary embodiment shown in FIG. 3, in the case of the exemplary embodiment shown in FIG. 6, the first hollow body voltage, the second hollow body voltage and the detector voltage are set by a single voltage supply unit, specifically by the first voltage supply unit 44.

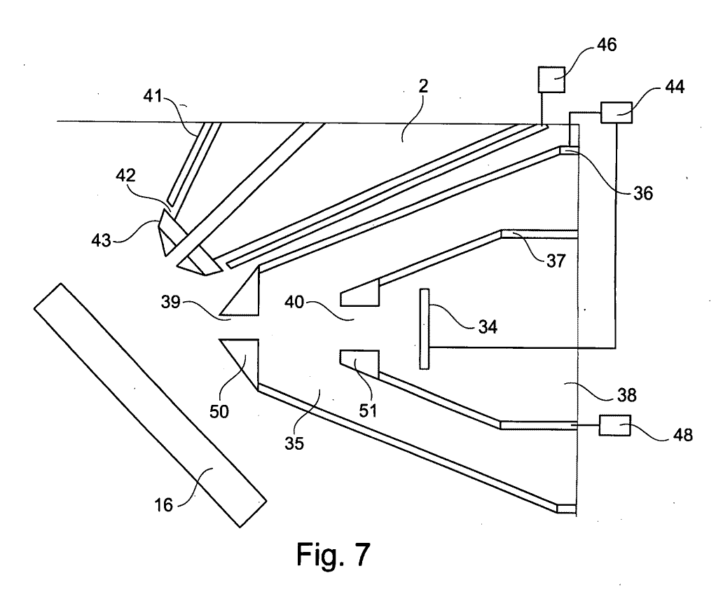

FIG. 7 shows a further exemplary embodiment. FIG. 7 is based on FIG. 3, as a result of which reference will first of all be made to the statements made above. In contrast to the exemplary embodiment shown in FIG. 3, in the case of the exemplary embodiment shown in FIG. 7, the first hollow body voltage and the detector voltage are set by a single voltage supply unit, specifically by the first voltage supply unit 44. The second hollow body voltage is set by the fifth voltage supply unit 48.

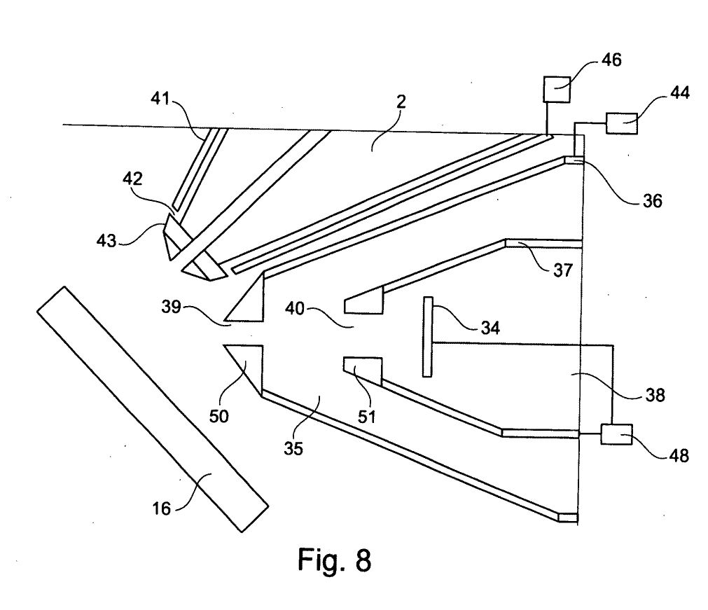

FIG. 8 once again shows a further exemplary embodiment. FIG. 8 is based on FIG. 3, as a result of which reference will first of all be made to the statements made above. In contrast to the exemplary embodiment shown in FIG. 3, in the case of the exemplary embodiment shown in FIG. 8, the second hollow body voltage and the detector voltage are set by a single voltage supply unit, specifically by the fifth voltage supply unit 48. The first hollow body voltage is set by the first voltage supply unit 44.

The described exemplary embodiments envisage the use of a first hollow body 36 and of a second hollow body 37. However, it is expressly mentioned that the system described herein is not restricted to the use of two hollow bodies. In fact, further embodiments of the system described herein envisage more than two hollow bodies being provided. Once again, further embodiments of the system described herein envisage only a single hollow body 36 being used, in whose first cavity 35 the second detector 34 is arranged.

The second detector 34 may be any desired chosen detector, for example a scintillation detector or a semiconductor detector. In the case of yet other embodiments, it is envisaged that the second detector 34 will be in the form of a spectrometric detection apparatus, for example an apparatus for carrying out SIMS, as already mentioned above.

In a further embodiment of the system described herein, at least one of the voltage supply units, specifically the first voltage supply unit 44, the second voltage supply unit 45, the third voltage supply unit 46, the fourth voltage supply unit 47 and the fifth voltage supply unit 48, are in the form of a bipolar voltage supply unit. This makes it possible to always set the mathematical sign of the potentials mentioned above such that positively or negatively charged first interaction particles reach the second detector 34.

In yet another embodiment of the system described herein, the sample potential can be set to a potential other than ground potential. In this case, the control electrode potential, the terminating electrode potential, the detector potential, the first hollow body potential and/or the second hollow body potential can be set to ground potential.

In a further embodiment of the system described herein, a potential is not provided for the entire first hollow body 36 and the entire second hollow body 37, but only for a first end 50 of the first hollow body 36 to be provided with the first hollow body potential, and for only a second end 51 of the second hollow body 37 to be provided with the second hollow body potential.

All the embodiments of the system described herein have the advantage that good detector efficiency is ensured when the first interaction particles are detected in the form of secondary ions. The sample potential, the first hollow body potential, the second hollow body potential, the detector potential, the terminating electrode potential and/or the control electrode potential are matched to one another such that an extraction field is generated such that a sufficient number of first interaction particles pass through the first inlet opening 39 and the second inlet opening 40, and are detected by the second detector 34.

Various embodiments discussed herein may be combined with each other in appropriate combinations in connection with the system described herein. Additionally, in some instances, the order of steps in the flowcharts, flow diagrams and/or described flow processing may be modified, where appropriate. Further, various aspects of the system described herein may be implemented using software, hardware, a combination of software and hardware and/or other computer-implemented modules or devices having the described features and performing the described functions. Software implementations of the system described herein may include executable code that is stored in a computer readable storage medium and executed by one or more procesors. The computer readable storage medium may include a computer hard drive, ROM, RAM, flash memory, portable computer storage media such as a CD-ROM, a DVD-ROM, a flash drive and/or other drive with, for example, a universal serial bus (USB) interface, and/or any other appropriate tangible storage medium or computer memory on which executable code may be stored and executed by a processor. The system described herein may be used in connection with any appropriate operating system.

Other embodiments of the invention will be apparent to those skilled in the art from a consideration of the specification or practice of the invention disclosed herein. It is intended that the specification and examples be considered as exemplary only, with the true scope and spirit of the invention being indicated by the following claims.

What is claimed is:

1. A particle beam device, comprising:
a sample chamber;
a sample which is arranged in the sample chamber;
a first particle beam column having a first optical axis, wherein the first particle beam column has a first beam generator for generating a first particle beam and has a first objective lens for focusing the first particle beam onto the sample, wherein, when the first particle beam strikes the sample, interactions between the first particle beam and the sample create first interaction particles;
a second particle beam column having a second optical axis, wherein the second particle beam column has a second beam generator for generating a second particle beam and has a second objective lens for focusing the second particle beam onto the sample, wherein, when the second particle beam strikes the sample, interactions between the second particle beam and the sample create second interaction particles;
at least one detector which is arranged in a first cavity in a first hollow body, wherein the first cavity has a first inlet opening, wherein a third axis runs from the first inlet opening to the detector, wherein the first optical axis of the first particle beam column and the second optical axis of the second particle beam column are arranged on one plane, wherein the third axis is arranged inclined with respect to or at right angles to the plane, wherein the sample is at a sample potential, wherein the first hollow body is at a first hollow body potential, and wherein a first hollow body voltage is a first potential difference between the first hollow body potential and the sample potential;
at least one control electrode, which is at a control electrode potential, arranged on the first particle beam column, a control electrode voltage being a third potential difference between the control electrode potential and the sample potential, wherein the second particle beam column has a terminating electrode which is at a terminating electrode potential, wherein a terminating electrode voltage is a fourth potential difference between the terminating electrode potential and the sample potential, and wherein at least one of: the first hollow body voltage, the control electrode voltage or the terminating electrode voltage is chosen such that the first interaction particles or the second interaction particles enter the first cavity in the first hollow body through the first inlet opening.

2. The particle beam device according to claim 1, further comprising at least one of the following features:
(i) the first hollow body voltage is set by a first voltage supply unit;
(ii) the control electrode voltage is set by a third voltage supply unit; or
(iii) the terminating electrode voltage is set by a fourth voltage supply unit.

3. The particle beam device according to claim 1, wherein the detector is at a detector potential, wherein a detector voltage is a second potential difference between the detector potential and the sample potential, and wherein at least one of: the first hollow body voltage, the detector voltage, the control electrode voltage or the terminating electrode voltage is chosen such that the first interaction particles or the second interaction particles enter the first cavity in the first hollow body through the first inlet opening.

4. The particle beam device according to claim 3, wherein the detector voltage is set by a second voltage supply unit.

5. The particle beam device according to claim 1, further comprising one of the following features:
(i) the control electrode is arranged on an outer surface of the first particle beam column;
(ii) the control electrode is arranged in a recess on an outer surface of the first particle beam column; or
(iii) the control electrode is arranged in a recess on an outer surface of the first particle beam column, wherein an outer surface of the control electrode and the outer surface of the first particle beam column form a continuous surface.

6. The particle beam device according to claim 1, further comprising one of the following features:
(i) the control electrode partially surrounds the first particle beam column; or
(ii) the control electrode completely surrounds the first particle beam column.

7. The particle beam device according to claim 1, further comprising at least one of the following features:
(i) the first hollow body potential is in the range from (−100) V to (−500) V;
(ii) the control electrode potential is in the range from 100 V to 800 V; or
(iii) the terminating electrode potential is in the range from (−50) V to (−200) V.

8. The particle beam device according to claim 3, wherein the detector potential is in the range from (−10) V to (−500) V.

9. The particle beam device according to claim 1, further comprising:
a second hollow body with a second cavity, wherein the second hollow body is at a second hollow body potential, and wherein a second hollow body voltage is a fifth potential difference between the second hollow body potential and the sample potential.

10. The particle beam device according to claim 9, wherein the second hollow body voltage is set by a fifth voltage supply unit.

11. The particle beam device according to claim 9, wherein the second hollow body potential is ground, and wherein the first hollow body potential is different than the second hollow body potential.

12. The particle beam device according to claim 9, wherein the first hollow body potential and the second hollow body potential are not ground.

13. The particle beam device according to claim 1, further comprising one of the following features:
(i) the first particle beam column is in the form of an ion beam column, and the second particle beam column is in the form of an electron beam column; or
(ii) the first particle beam column is in the form of an ion beam column, and the second particle beam column is in the form of an ion beam column.

14. A method for operation of a particle beam device, comprising:
providing a first hollow body voltage;
providing a control electrode voltage;
providing a terminating electrode voltage; and
setting at least one of: the first hollow body voltage, the control electrode voltage, or the terminating electrode voltage such that first interaction particles or second interaction particles enter a first cavity in the first hollow body through a first inlet opening in the first cavity.

15. The method according to claim 14, further comprising:
providing a detector voltage; and
setting at least one of: the first hollow body voltage, the detector voltage, the control electrode voltage or the terminating electrode voltage such that the first interaction particles or the second interaction particles enter the first cavity in the first hollow body through the first inlet opening in the first cavity.

16. The method according to claim 14, wherein the particle beam device includes:
a sample chamber;
a sample which is arranged in the sample chamber;
a first particle beam column having a first optical axis, wherein the first particle beam column has a first beam generator for generating a first particle beam and has a first objective lens for focusing the first particle beam onto the sample, wherein, when the first particle beam strikes the sample, interactions between the first particle beam and the sample create first interaction particles;
a second particle beam column having a second optical axis, wherein the second particle beam column has a second beam generator for generating a second particle beam and has a second objective lens for focusing the second particle beam onto the sample, wherein, when the second particle beam strikes the sample, interactions between the second particle beam and the sample create second interaction particles;
at least one detector which is arranged in the first cavity in the first hollow body, wherein the first cavity has the first inlet opening, wherein a third axis runs from the first inlet opening to the detector, wherein the first optical axis of the first particle beam column and the second optical axis of the second particle beam column are arranged on one plane, wherein the third axis is arranged inclined with respect to or at right angles to the plane, wherein the sample is at a sample potential, wherein the first hollow body is at a first hollow body potential, and wherein the first hollow body voltage is a first potential difference between the first hollow body potential and the sample potential;
at least one control electrode, which is at a control electrode potential, arranged on the first particle beam column, the control electrode voltage being a third potential difference between the control electrode potential and the sample potential, wherein the second particle beam column has a terminating electrode which is at a terminating electrode potential, wherein the terminating electrode voltage is a fourth potential difference between the terminating electrode potential and the sample potential.
